(19) United States
(12) Patent Application Publication
(10) Pub. No.: US 2024/0026540 A1
(43) Pub. Date: Jan. 25, 2024

(54) SUBSTRATE PROCESSING APPARATUS AND EXHAUST METHOD THEREOF

(71) Applicant: SAMSUNG ELECTRONICS CO., LTD., Suwon-si (KR)

(72) Inventors: Jungkuk LEE, Suwon-si (KR); Kitaek SONG, Suwon-si (KR); Jongkuk WON, Suwon-si (KR); Sangmi YOON, Suwon-si (KR); Junhyun LEE, Suwon-si (KR)

(73) Assignee: SAMSUNG ELECTRONICS CO., LTD., Suwon-si (KR)

(21) Appl. No.: 18/215,454

(22) Filed: Jun. 28, 2023

(30) Foreign Application Priority Data
Jul. 20, 2022 (KR) 10-2022-0089882

(51) Int. Cl. C23C 16/52; C23C 16/44

(52) U.S. Cl. CPC C23C 16/52; C23C 16/4408

(57) ABSTRACT

An exhaust method of a substrate processing apparatus, includes: measuring a first flow rate for each of process gases included in a mixed gas supplied to a process chamber; determining, based on the first flow rate, a lower explosion limit of the mixed gas and a first volume percentage of a combustible process gas among the process gases; determining a supply flow rate of a first dilution gas based on the first volume percentage and the lower explosion limit; and supplying, at the determined supply flow rate of the first dilution gas, the first dilution gas to the mixed gas in the process chamber.

### CROSS-REFERENCE TO RELATED APPLICATION

This application claims priority to Korean Patent Application No. 10-2022-0089882, filed on Jul. 20, 2022, in the Korean Intellectual Property Office, the disclosure of which is incorporated by reference herein in its entirety.

### BACKGROUND

The present disclosure relates to a substrate processing apparatus and an exhaust method of the substrate processing apparatus. More particularly, the disclosure relates to a substrate processing apparatus that does not include a separate gas sensor, and an exhaust method of the substrate processing apparatus.

In the manufacturing process of a semiconductor device, a mixed gas including various process gases is used. In particular, with the trend toward miniaturization of semiconductor devices, a mixed gas containing more and more types of process gases is being used to manufacture the semiconductor device. The mixed gas used in the manufacturing process of the semiconductor device is discharged from the substrate processing apparatus through a separate discharge process. However, as the mixed gas includes more types of process gases, a safety problem and an environmental problem occur in the process of discharging the mixed gas.

### SUMMARY

Example embodiments provide a substrate processing apparatus capable of monitoring a mixed gas in real time to prevent an explosion accident caused by the mixed gas and an exhaust method thereof.

In addition, example embodiments relate to a substrate processing apparatus capable of reducing costs that may occur due to the use of gas sensors by not using separate gas sensors and an exhaust method thereof.

According to an aspect of an example embodiment, an exhaust method of a substrate processing apparatus, includes: measuring a first flow rate for each of process gases included in a mixed gas supplied to a process chamber; determining, based on the first flow rate, a lower explosion limit of the mixed gas and a first volume percentage of a combustible process gas among the process gases; determining a supply flow rate of a first dilution gas based on the first volume percentage and the lower explosion limit; and supplying, at the determined supply flow rate of the first dilution gas, the first dilution gas to the mixed gas in the process chamber.

According to an aspect of an example embodiment, a substrate processing apparatus includes: a mixed gas supply device configured to supply a mixed gas in which process gases are mixed; a process chamber located downstream from the mixed gas supply device and configured to perform substrate processing using the mixed gas; a pump located downstream from the process chamber; a scrubber located downstream from the pump and configured to scrub the mixed gas discharged from the process chamber; a dilution gas supply device configured to supply dilution gas to the mixed gas; and a control device configured to control the dilution gas supply device, wherein the control device is configured to: determine, based on a first flow rate for each of the process gases, a lower explosion limit of the mixed gas and a first volume percentage of a combustible process gas among the process gases, and control the dilution gas supply device to determine a supply flow rate of a first dilution gas based on the lower explosion limit and the first volume percentage.

According to an aspect of an example embodiment, an exhaust method of substrate processing apparatus, includes: measuring a first flow rate for each of process gases included in a mixed gas supplied to a process chamber; determining a lower explosion limit of the mixed gas based on the first flow rate; measuring a second flow rate of a first dilution gas supplied to a pump located downstream from the process chamber; determining a first volume percentage of a combustible process gas among the process gases based on the first flow rate and the second flow rate; determining a supply flow rate of a second dilution gas based on the first volume percentage and the lower explosion limit; supplying, at the determined supply rate of the second dilution gas, the second dilution gas to a discharge line connected to the pump; and discharging an exhaust gas in which the mixed gas, the first dilution gas, and the second dilution gas are mixed.

### BRIEF DESCRIPTION OF THE DRAWINGS

The above and other aspects and features will be more apparent from the following description of example embodiments taken in conjunction with the accompanying drawings, in which:

FIG. 1 is a block diagram illustrating a substrate processing apparatus according to an example embodiment;

FIG. 2 is a flowchart illustrating a method of exhausting a substrate processing apparatus according to an example embodiment;

FIG. 3 is a flowchart illustrating an exhaust method of a substrate processing apparatus according to an example embodiment; and

FIG. 4 is a flowchart illustrating an exhaust method of a substrate processing apparatus according to an example embodiment.

### DETAILED DESCRIPTION

Hereinafter, example embodiments will be described in detail with reference to the accompanying drawings. The same reference numerals are used for the same components in the drawings, and duplicate descriptions thereof are omitted.

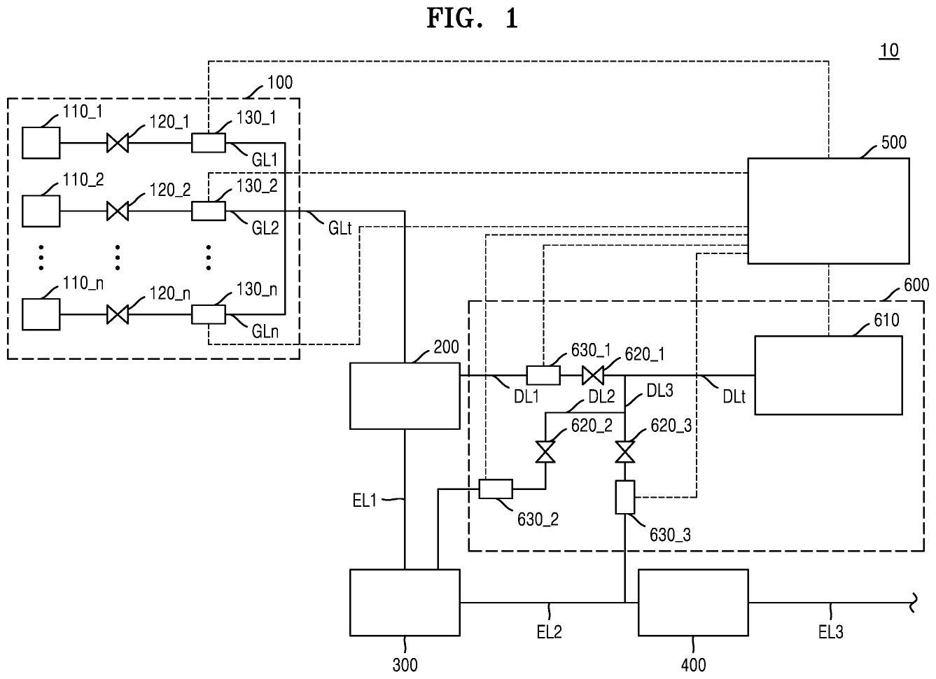

FIG. 1 is a block diagram illustrating a substrate processing apparatus 10 according to an example embodiment.

Referring to FIG. 1, the substrate processing apparatus 10 may include a mixed gas supply device 100, a process chamber 200, a pump 300, a scrubber 400, a control device 500, and a dilution gas supply device 600.

The mixed gas supply device 100 includes process gas sources 110_1, 110_2, . . . , 110_n, process gas valves 120_1, 120_2, . . . , 120_n, and mass flow controllers (MFCs) 130_1, 130_2, . . . , 130_n.

The process gas sources 110_1, 110_2, . . . , 110_n may supply a plurality of process gases. Process gases supplied by the process gas sources 110_1, 110_2, . . . , 110_n may be different from each other. The plurality of process gases may be, for example, process gases used in an atomic layer deposition (ALD) process, but are not limited thereto. In an example embodiment, at least one of the process gases may be a combustible process gas. The combustible process gas may be, for example, any one of NH₃, H₂, and Hexachloro Disilane (HCDS).

The process gas supply lines GL1, GL2, . . . , GLn may be respectively connected to the process gas supply sources 110_1, 110_2, . . . , 110_n. The process gases respectively supplied by the process gas supply sources 110_1, 110_2, . . . , 110_n may flow toward the process chamber 200 through the process gas supply lines GL1, GL2, GLn.

The process gas valves 120_1, 120_2, . . . , 120_n may be respectively disposed on the process gas supply lines GL1, GL2, . . . , GLn downstream from the process gas supply sources 110_1, 110_2, . . . , 110_n. Depending on whether the process gas valves 120_1, 120_2, . . . , 120_n are opened or closed, each of the process gases may or may not be supplied to the process chamber 200.

The MFCs 130_1, 130_2, . . . , 130_n may be disposed on the process gas supply lines GL1, GL2, . . . , GLn downstream from the process gas valves 120_1, 120_2, . . . , 120_n. The MFCs 130_1, 130_2, . . . , 130_n may include a receiver and a transmitter capable of transmitting and receiving electrical signals to and from the control device 500. In an example embodiment, each of the MFCs 130_1, 130_2, . . . , 130_n may measure flow rate information of process gases flowing through the process gas supply lines GL1, GL2, . . . , GLn respectively corresponding to the MFCs 130_1, 130_2, . . . , 130_n in real time. In this case, the flow rate information measured in real time may be transmitted to the control device 500 through the transmitter.

The process gas supply lines GL1, GL2, . . . , GLn may be merged into the mixed gas supply line GLt downstream from the MFCs 130_1, 130_2, . . . , 130_n. The mixed gas supply line GLt may be connected to the process chamber 200 to supply a mixed gas in which respective process gases are mixed into the process chamber 200.

The process chamber 200 may be located downstream from the mixed gas supply device 100. In the process chamber 200, a substrate treatment process using the mixed gas supplied by the mixed gas supply device 100 may be performed. The substrate treatment process may be, for example, an etching process, an exposure process, and a thin film process, but is not limited thereto.

The first discharge line EL1 may connect the process chamber 200 to the pump 300. After the substrate treatment process is performed, the mixed gas used in the substrate treatment process may be discharged from the process chamber 200 and flow to the pump 300 through the first discharge line EL1.

The pump 300 may be located downstream from the process chamber 200. The pump 300 may adjust the pressure inside the process chamber 200 and facilitate discharge of the mixed gases remaining in the process chamber 200 toward the pump 300 after the substrate treatment process is performed. In FIG. 1, the pump 300 is illustrated as being one pump, but the disclosure is not limited thereto.

The second discharge line EL2 may connect the pump 300 to the scrubber 400. The mixed gas passing through the pump 300 may flow to the scrubber 400 through the second discharge line EL.

The scrubber 400 may be located downstream from the pump 300. The scrubber 400 may decompose and/or purify the mixed gas that has passed through the pump 300 in a safe state. The scrubber 400 may be at least one of a dry scrubber, a wet scrubber, a mixed scrubber, and a plasma scrubber, according to the characteristics of the mixed gas.

The third discharge line EL3 may be connected to the scrubber 400. The mixed gas processed through the scrubber 400 may be discharged through the third discharge line EL3.

The control device 500 may control the operation of the dilution gas supply device 600. For example, the control device 500 may be configured to transmit and receive electrical signals to and from the dilution gas supply device 600, and may be configured to control the operation of the dilution gas supply device 600.

The control device 500 may be implemented in hardware, firmware, software, or any combination thereof. For example, the control device 500 may be a computing device, such as a workstation computer, a desktop computer, a laptop computer, or a tablet computer. For example, the control device 500 may include a memory device, such as Read Only Memory (ROM) and Random Access Memory (RAM), and a processor configured to perform a preset operation and algorithm, for example, a microprocessor, a central processing unit (CPU), a graphics processing unit (GPU), and the like. In addition, the control device 500 may include a receiver and a transmitter for receiving and transmitting an electrical signal.

In an example embodiment, based on the flow rate of the process gases transmitted from each of the MFCs 130_1, 130_2, . . . , 130_n, the control device 500 may calculate a lower explosion limit of the mixed gas in which the process gases are mixed and a volume percentage of the combustible process gas. Thereafter, the control device 500 may control the operation of the dilution gas supply device 600 to determine a supply flow rate of the dilution gas based on the lower explosion limit and the volume percentage.

In an example embodiment, the control device 500 may calculate a lower explosion limit of the mixed gas in which the process gases are mixed based on the flow rate of the process gases, and use the flow rate of the process gases and the flow rate of the dilution gas to calculate the volume percentage of the combustible process gas. Thereafter, the control device 500 may control the operation of the dilution gas supply device 600 to determine the supply flow rate of the dilution gas based on the lower explosion limit and the volume percentage.

In an example embodiment, the control device 500 may calculate a lower explosion limit of the mixed gas in which the process gases are mixed, an upper explosion limit of the mixed gas, and a volume percentage of the combustible process gas using the flow rate of the process gases transmitted from each of the MFCs 130_1, 130_2, . . . , 130_n. After that, the control device 500 may control the operation of the dilution gas supply device 600 to determine the supply flow rate of the dilution gas based on the lower explosion limit, the upper explosion limit, and the volume percentage.

In an example embodiment, the control device 500 may calculate the lower explosion limit of the mixed gas in which the process gases are mixed and the upper explosion limit of the mixed gas using the flow rate of the process gases, and calculate the volume percentage of the combustible process gas based on the flow rate of the process gases and the flow rate of the dilution gas. The control device 500 may also control the operation of the dilution gas supply device 600 to determine the supply flow rate of the dilution gas based on the lower explosion limit, the upper explosion limit, and the volume percentage.

In an example embodiment, unlike the example embodiment shown in FIG. 1, the substrate processing apparatus 10 may include a first control device (not shown) and a second control device (not shown). In this case, the first control device may calculate the lower explosion limit and the volume percentage, or the lower explosion limit, the upper explosion limit, and the volume percentage. Thereafter, the first control device may transmit the lower explosion limit and the volume percentage, or the lower explosion limit, the upper explosion limit, and the volume percentage, to the second control device. The second control device may control the operation of the dilution gas supply device 600 to determine the supply flow rate of the dilution gas based on the lower explosion limit and the volume percentage, or control the operation of the dilution gas supply device 600 to determine the supply flow rate of the dilution gas based on the lower explosion limit, the upper explosion limit, and the volume percentage.

The dilution gas supply device 600 may include a dilution gas source 610, first, second, and third dilution gas valves 620_1, 620_2, and 620_3, and first, second, and third MFCs 630_1, 630_2, and 630_3.

The dilution gas supply source 610 may supply the dilution gas to the mixed gas in the substrate processing apparatus 10. In an example embodiment, the dilution gas supply device 600 may supply the dilution gas to the mixed gas in the process chamber 200. In another example embodiment, the dilution gas supply device 600 may supply the dilution gas to the mixed gas in the pump 300. In another example embodiment, the dilution gas supply device 600 may supply the dilution gas to the mixed gas from the second discharge line EL2. In an example embodiment, the dilution gas may include nitrogen.

The dilution gas supply line DLt may be connected to the dilution gas source 610. The dilution gas supplied from the dilution gas source 610 may flow through the dilution gas supply line DLt and may be supplied to the mixed gas in the substrate processing apparatus 10. The dilution gas supply line DLt may branch into a first dilution gas supply line DL1, a second dilution gas supply line DL2, and a third dilution gas supply line DL3.

The first dilution gas supply line DL1 may be connected to the process chamber 200, the second dilution gas supply line DL2 may be connected to the pump 300, and the third dilution gas supply line DL3 may be connected to the second discharge line EL2. The first, second, and third dilution gas supply lines DL1, DL2, and DL3 may respectively have first, second, and third dilution gas valves 620_1, 620_2, and 620_3 disposed thereon corresponding to the first, second, and third dilution gas supply lines DL1, DL2, and DL3. Depending on whether the first, second, and third dilution gas valves 620_1, 620_2, and 620_3 are opened or closed, dilution gas may or may not be supplied to the mixed gas. For example, when the first dilution gas valve 620_1 is opened and the second dilution gas valve 620_2 and the third dilution gas valve 620_3 are closed, the dilution gas may be supplied to the mixed gas in the process chamber 200, but may not be supplied from the pump 300 and the second discharge line EL2.

The first, second, and third MFCs 630_1, 630_2, and 630_3 may be respectively disposed on the first, second, and third dilution supply lines DL1, DL2, and DL3, and may be located downstream from the first, second, and third dilution gas valves 620_1, 620_2, and 620_3. The first, second, and third MFCs 630_1, 630_2, and 630_3 may measure the flow rate of dilution gas supplied through the first, second, and third dilution supply lines DL1, DL2, and DL3 in real time. The flow rate may be transmitted to the control device 500.

In an example embodiment, unlike the example embodiment shown in FIG. 1, the dilution gas supply device 600 may not include the first, second, and third MFCs 630_1, 630_2, and 630_3. In this case, the dilution gas supply device 600 may transmit the set supply flow rate of the dilution gas to the control device 500 without separately measuring the flow rate of the dilution gas.

In an example embodiment, the dilution gas supply device 600 may further include a receiver and a transmitter capable of transmitting and receiving electrical signals to and from the control device 500.

The substrate processing apparatus 10 according to an example embodiment may calculate in real time a lower explosion limit of a mixed gas in the substrate processing apparatus 10 and a volume percentage of the combustible process gas among the process gases included in the mixed gas through the control device 500. Accordingly, even when the flow rate of each of the process gases used in the manufacturing process of the semiconductor device is changed due to the change of the process conditions, by monitoring the lower explosion limit of the mixed gas in real time, it is possible to cope with a change in process conditions, thereby reducing the risk of explosion of the mixed gas in the substrate processing apparatus 10. In addition, without including a separate gas sensor, by calculating the lower explosion limit of the mixed gas through the flow rate of each process gas measured by the MFCs 130_1, 130_2, . . . , 130_n and the flow rate of the dilution gas measured by the first, second, and third MFCs 630_1, 630_2, 630_3, the cost that may be caused by using a separate gas sensor may be reduced.

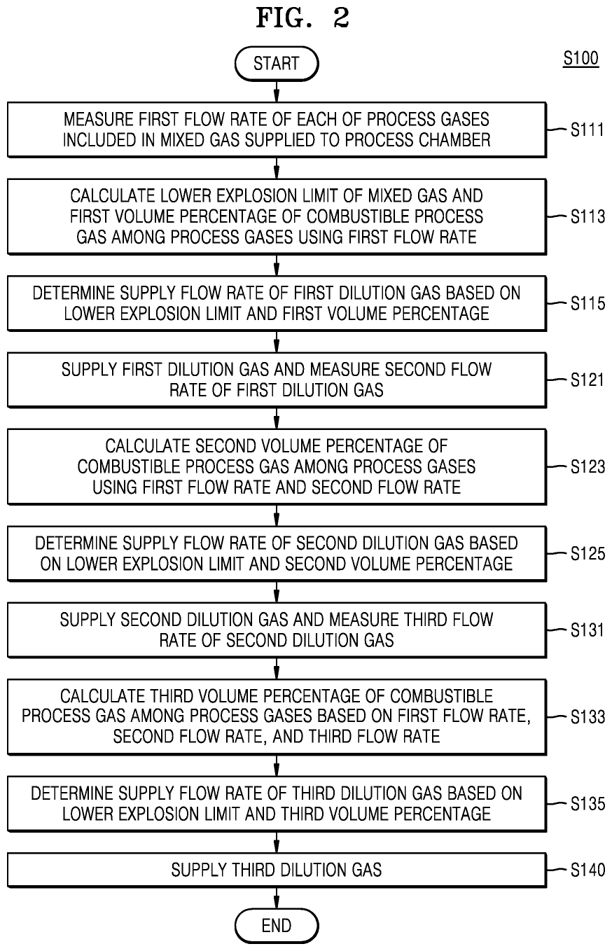

FIG. 2 is a flowchart illustrating an exhaust method S100 of a substrate processing apparatus according to an example embodiment.

Referring to FIGS. 1 and 2 together, first, the MFCs 130_1, 130_2, . . . , 130_n may first measure a first flow rate of each of the process gases included in the mixed gas supplied from the mixed gas supply device 100 to the process chamber 200 (S111). In this case, at least one of the process gases may be a combustible process gas. The measured first flow rate may be transmitted from the MFCs 130_1, 130_2, 130_n to the control device 500.

After operation S111 is performed, the control device 500 may calculate a lower explosion limit of the mixed gas and a first volume percentage of the combustible process gas using the first flow rate (S113). At this time, the lower explosion limit of the mixed gas may be calculated using the following Le Chatelier equation:

$$\frac{V}{L} = \frac{V 1}{L 1} + \frac{V 2}{L 2} + \frac{V 3}{L 3} + ⋯ + \frac{Vn}{Ln}$$

Here, V refers to the flow rate of the mixed gas, L refers to the lower explosion limit of the mixed gas, V1, V2, V3, . . . , Vn refer to the flow rate of the combustible process gas among the process gases included in the mixed gas, and L1, L2, L3, . . . , Ln refer to the lower explosion limit of the combustible process gas. For example, when the process gases included in the mixed gas are N₂, NH₃, H₂, N₂O, O₂, NO, F₂, HF, and HCDS, among the process gases, NH₃, H₂, and HCDS correspond to combustible process gases. At this time, because the lower explosion limit of NH₃ is 15.0%, the lower explosion limit system of H₂ is 4%, and the lower explosion limit of HCDS is 7%, the lower explosion limit L of the mixed gas is calculated as

$$\frac{V}{\frac{{V}_{1}}{15} + \frac{{V}_{2}}{4} + \frac{{V}_{3}}{7}} .$$

Because V, V1, V2, and V3 may be obtained through the first flow rate, the lower explosion limit L of the mixed gas may be calculated.

The first volume percentage of the combustible process gas may be calculated by dividing the flow rate of the combustible gas by the flow rate of the mixed gas and multiplying the obtained value by 100.

After operation S113 is performed, the control device 500 may determine the supply flow rate of the first dilution gas based on the first volume percentage and the lower explosion limit of the mixed gas (S115). In an example embodiment, when the substrate processing apparatus 10 includes a first control device and a second control device as shown in FIG. 1, until operation S113, operations may be performed by the first control device, and from operation S115, operations may be performed by the second control device, however an example embodiment may not be limited to the aforementioned configuration.

Specifically, when the first volume percentage is greater than the lower explosion limit of the mixed gas, it may be stated that the explosion risk of the mixed gas is high. Accordingly, the control device 500 may control the operation of the dilution gas supply device 600 to supply the first dilution gas to the process chamber 200 through the first dilution gas supply line DL1. The first dilution gas supplied into the process chamber 200 may be mixed with the mixed gas to become a first exhaust gas, and may be discharged from the process chamber 200. On the other hand, when the first volume percentage is less than the lower explosion limit of the mixed gas, it may be stated that the explosion risk of the mixed gas is low. Accordingly, the mixed gas may be discharged through the pump 300 and the scrubber 400 without separately supplying the first dilution gas. In an example embodiment, the first dilution gas may include nitrogen.

When the supply of the first dilution gas into the process chamber 200 is performed in operation S115, a second flow rate of the first dilution gas may be measured next (S121). The second flow rate of the first dilution gas may be measured through the first MFC 630_1. The measured second flow rate may be transmitted to the control device 500.

After operation S121 is performed, the control device 500 may calculate a second volume percentage of the combustible process gas using the first flow rate and the second flow rate (S123).

The second volume percentage may be calculated by dividing the flow rate of the combustible process gas by the flow rate of the first exhaust gas, that is, the sum of the flow rate of the mixed gas and the flow rate of the first dilution gas, and multiplying the obtained value by 100.

After operation S123 is performed, the control device 500 may determine the supply flow rate of the second dilution gas based on the second volume percentage and the lower explosion limit of the first exhaust gas (S125). Because the first exhaust gas is a gas in which the mixed gas and the first dilution gas are mixed, and the first dilution gas is not a combustible gas, the lower explosion limit of the first exhaust gas is the same as the lower explosion limit of the mixed gas. In an example embodiment, when the substrate processing apparatus 10 includes a first control device and a second control device as shown in FIG. 1, until operation S123, operations may be performed by the first control device, and from operation S125, operations may be performed by the second control device, however an example embodiment may not be limited to the aforementioned configuration.

Specifically, when the second volume percentage is greater than the lower explosion limit of the first exhaust gas, the risk of explosion of the first exhaust gas may be high. Accordingly, the control device 500 may control the operation of the dilution gas supply device 600 to supply the second dilution gas to the pump 300 through the second dilution gas supply line DL2. The second dilution gas supplied into the pump 300 may be mixed with the first exhaust gas to become a second exhaust gas, and may be discharged from the pump 300. On the other hand, when the second volume percentage is less than the lower explosion limit of the first exhaust gas, it may be stated that the explosion risk of the first exhaust gas is low. Accordingly, the first exhaust gas may be discharged through the pump 300 and the scrubber 400 without separately supplying the second dilution gas. In an example embodiment, the second dilution gas may include the same material as the first dilution gas. For example, the first dilution gas and the second dilution gas may include nitrogen, however an example embodiment may not be limited thereto.

When the supply of the second dilution gas into the pump 300 is performed in operation S125, a third flow rate of the second dilution gas may be measured (S131). A third flow rate of the second dilution gas may be measured through the second MFC 630_2. The measured third flow rate may be transmitted to the control device 500.

After operation S131 is performed, the control device 500 may calculate a third volume percentage of the combustible process gas using the first flow rate, the second flow rate, and the third flow rate (S133).

The third volume percentage may be calculated by dividing the flow rate of the combustible process gas by the flow rate of the second exhaust gas, that is, the sum of the flow rate of the mixed gas, the flow rate of the first dilution gas, and the flow rate of the second dilution gas, and multiplying the obtained value by 100.

After operation S133 is performed, the control device 500 may determine the supply flow rate of the third dilution gas based on the third volume percentage and the lower explosion limit of the second exhaust gas (S135). At this time, because the second exhaust gas is a gas in which the first exhaust gas and the second dilution gas are mixed, and the second dilution gas is not a combustible gas, the lower explosion limit of the second exhaust gas is the same as the lower explosion limit of the first exhaust gas. Because the lower explosion limit of the first exhaust gas is the same as the lower explosion limit of the mixed gas as described above, the lower explosion limit of the second exhaust gas is the same as the lower explosion limit of the mixed gas. In an example embodiment, when the substrate processing apparatus 10 includes a first control device and a second control device as shown in FIG. 1, until operation S133, operations may be performed by the first control device, and from operation S135, operations may be performed by the second control device.

Specifically, when the third volume percentage is greater than the lower explosion limit of the second exhaust gas, the explosion risk of the second exhaust gas may be high. Accordingly, the control device 500 may control the operation of the dilution gas supply device 600 to supply the third dilution gas to the discharge line EL2 through the third dilution gas supply line DL3 (S140). The second dilution gas supplied to the discharge line EL2 may be mixed with the second exhaust gas to become a third exhaust gas, and may be discharged through the scrubber 400 through the second discharge line EL2. On the other hand, when the third volume percentage is less than the lower explosion limit of the second exhaust gas, it may be stated that the explosion risk of the second exhaust gas is low. Therefore, the second exhaust gas may be discharged through the scrubber 400 without separately supplying the third dilution gas. In an example embodiment, the third dilution gas may include the same material as the first dilution gas and the second dilution gas. For example, the first dilution gas, the second dilution gas, and the third dilution gas may include nitrogen.

The exhaust method S100 of the substrate processing apparatus according to an example embodiment may calculate in real time the lower explosion limit of the mixed gas in the substrate processing apparatus 10 and the volume percentage of the combustible process gas included in the mixed gas. Accordingly, even when the flow rate of each of the process gases used in the manufacturing process of the semiconductor device is changed due to the change of the process conditions, by monitoring the lower explosion limit of the mixed gas in real time, it is possible to cope with a change in process conditions, thereby reducing the risk of explosion of the mixed gas in the substrate processing apparatus 10. In addition, by calculating the lower explosion limit of the mixed gas through the flow rate of each process gas and the flow rate of the dilution gas without using a separate gas sensor, costs due to the use of a separate gas sensor may be reduced.

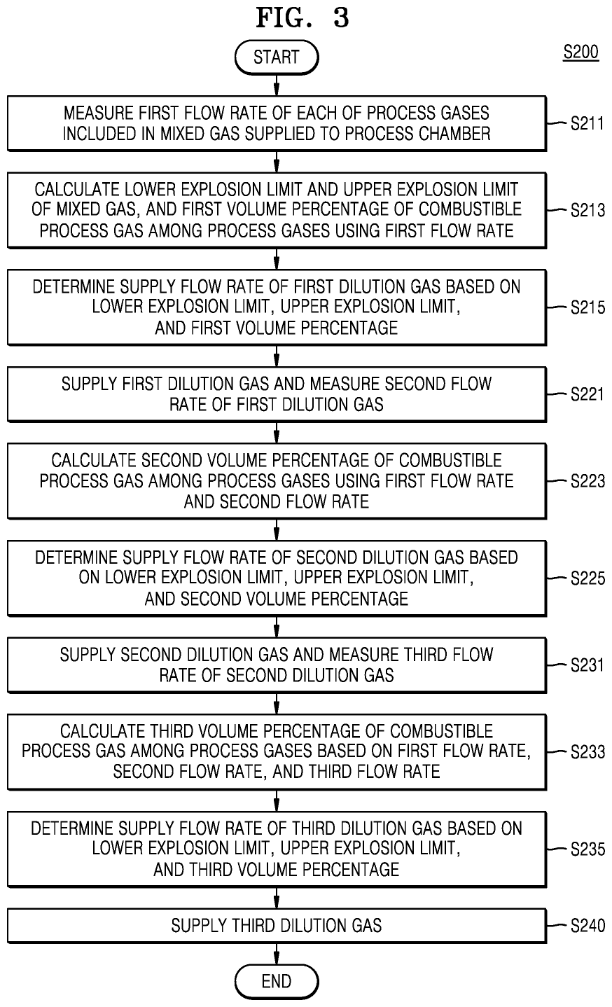

FIG. 3 is a flowchart illustrating a method S200 of exhausting a substrate processing apparatus according to an example embodiment of the disclosure. Each of the operations shown in FIG. 3 is similar to the corresponding operations of the exhaust method S100 of the substrate processing apparatus described with reference to the example embodiment shown in FIG. 2, and therefore, the following description will focus on the differences.

Referring to FIGS. 1 and 3 together, first, the MFCs 130_1, 130_2, . . . , 130_n may first measure a first flow rate of each of the process gases included in the mixed gas supplied from the mixed gas supply device 100 to the process chamber 200 (S211). In this case, at least one of the process gases may be a combustible process gas. The measured first flow rate may be transmitted from the MFCs 130_1, 130_2, . . . , 130_n to the control device 500.

After operation S211 is performed, the control device 500 may calculate a lower explosion limit of the mixed gas, an upper explosion limit of the mixed gas, and a first volume percentage of the combustible process gas based on the first flow rate (S213). In this case, the lower explosion limit of the mixed gas and the upper explosion limit of the mixed gas may be calculated using the Le Chatelier equation described above with reference to FIGS. 1 and 2. When calculating the upper explosion limit of the mixed gas, in the above-mentioned Le Chatelier equation, L refers to the upper explosion limit of the mixed gas, and L1, L2, L3, . . . , Ln refer to an upper explosion limit of the combustible process gas.

The first volume percentage of the combustible process gas may be calculated by dividing the flow rate of the combustible gas by the flow rate of the mixed gas and multiplying the obtained value by 100.

After operation S213 is performed, the control device 500 may determine the supply flow rate of the first dilution gas based on the first volume percentage, the upper explosion limit of the mixed gas, and the lower explosion limit of the mixed gas (S215). Specifically, when the first volume percentage is greater than the lower explosion limit of the mixed gas and less than the upper explosion limit of the mixed gas, the explosion risk of the mixed gas may be high. Accordingly, the control device 500 may control the operation of the dilution gas supply device 600 to supply the first dilution gas to the process chamber 200 through the first dilution gas supply line DLT. The first dilution gas supplied into the process chamber 200 may be mixed with the mixed gas to become a first exhaust gas, and may be discharged from the process chamber 200.

When the supply of the first dilution gas into the process chamber 200 is performed in operation S215, a second flow rate of the first dilution gas may be measured next (S221).

After operation S221 is performed, the control device 500 may calculate a second volume percentage of the combustible process gas based on the first flow rate and the second flow rate (S223).

The second volume percentage may be calculated by dividing the flow rate of the combustible process gas by the flow rate of the first exhaust gas, that is, the sum of the flow rate of the mixed gas and the flow rate of the first dilution gas, and multiplying the obtained value by 100.

After operation S223 is performed, the control device 500 may determine a supply flow rate of the second dilution gas based on the second volume percentage, an upper explosion limit of the first exhaust gas, and a lower explosion limit of the first exhaust gas (S225). At this time, because the first exhaust gas is a gas in which the mixed gas and the first dilution gas are mixed, and the first dilution gas is not a combustible gas, the lower explosion limit of the first exhaust gas is the same as the lower explosion limit of the mixed gas, and the upper explosion limit of the first exhaust gas is the same as the upper explosion limit of the mixed gas.

Specifically, when the second volume percentage is greater than the lower explosion limit of the first exhaust gas and less than the upper explosion limit of the first exhaust gas, the risk of explosion of the first exhaust gas may be high. Accordingly, the control device 500 may control the operation of the dilution gas supply device 600 to supply the second dilution gas to the pump 300 through the second dilution gas supply line DL2. The second dilution gas supplied into the pump 300 may be mixed with the first exhaust gas to become a second exhaust gas, and may be discharged from the pump 300.

When the supply of the second dilution gas into the pump 300 is performed in operation S225, a third flow rate of the second dilution gas may be measured next (S231).

After operation S231 is performed, the control device 500 may calculate a third volume percentage of the combustible process gas based on the first flow rate, the second flow rate, and the third flow rate (S233).

The third volume percentage may be calculated by dividing the flow rate of the combustible process gas by the flow rate of the second exhaust gas, that is, the sum of the flow rate of the mixed gas, the flow rate of the first dilution gas, and the flow rate of the second dilution gas, and multiplying the obtained value by 100.

After operation S233 is performed, the control device 500 may determine the supply flow rate of the third dilution gas based on the third volume percentage, a lower explosion limit of the second exhaust gas, and an upper explosion limit of the second exhaust gas (S235). At this time, because the second exhaust gas is a gas in which the first exhaust gas and the second dilution gas are mixed, and the second dilution gas is not a combustible gas, the lower explosion limit of the second exhaust gas is the same as the lower explosion limit of the first exhaust gas, and the upper explosion limit of the second exhaust gas is the same as the upper explosion limit of the first exhaust gas. Because the lower explosion limit and the upper explosion limit of the first exhaust gas are the same as the lower explosion limit and the upper explosion limit of the mixed gas, respectively, as described above, a lower explosion limit and an upper explosion limit of the second exhaust gas are the same as a lower explosion limit and an upper explosion limit of the mixed gas.

Specifically, when the third volume percentage is greater than the lower explosion limit of the second exhaust gas and less than the upper explosion limit of the second exhaust gas, the explosion risk of the second exhaust gas may be high. Accordingly, the control device 500 may control the operation of the dilution gas supply device 600 to supply the third dilution gas to the second discharge line EL2 through the third dilution gas supply line DL3 (S240). The third dilution gas supplied to the second discharge line EL2 may be mixed with the second exhaust gas to become a third exhaust gas, and may be discharged through the scrubber 400 through the second discharge line EL2.

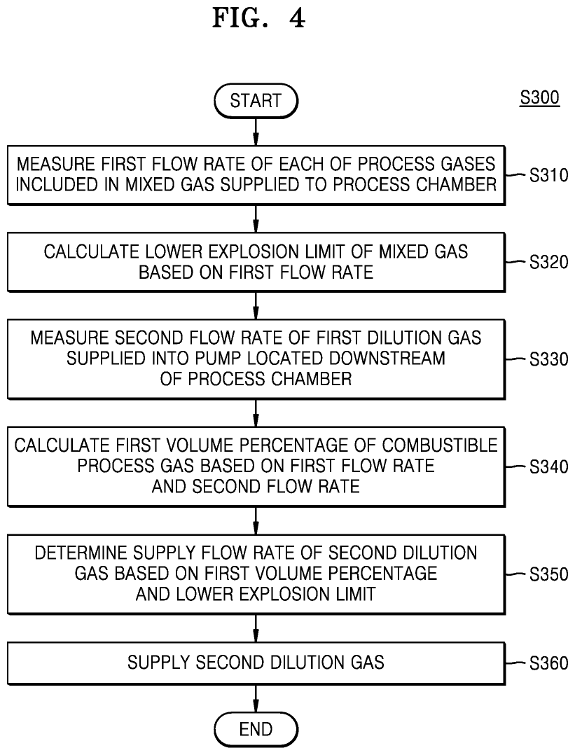

FIG. 4 is a flowchart illustrating an exhaust method S300 of a substrate processing apparatus according to an example embodiment. Each of the operations shown in FIG. 4 is similar to the corresponding operations of the exhaust method S100 of the substrate processing apparatus described with reference to the example embodiment shown in FIG. 2, and therefore, the following description will focus on the differences.

Referring to FIGS. 1 and 4 together, first, the MFCs 130_1, 130_2, . . . , 130_n may first measure a first flow rate of each of the process gases included in the mixed gas supplied from the mixed gas supply device 100 to the process chamber 200 (S310). In this case, at least one of the process gases may be a combustible process gas. The measured first flow rate may be transmitted from the MFCs 130_1, 130_2, . . . , 130_n to the control device 500.

After operation S310 is performed, the control device 500 may calculate a lower explosion limit of the mixed gas based on the first flow rate (S320). In this case, the lower explosion limit of the mixed gas may be calculated using the Le Chatelier equation described above with reference to FIGS. 1 and 2.

After operation S320 is performed, the second flow rate of the first dilution gas supplied into the pump 300 may be measured (S330). The second flow rate may be measured, for example, through the second MFC 630_2. Unlike the example embodiment shown in FIG. 1, when the first, second, and third MFCs 630_1, 630_2, and 630_3 are omitted, the supply flow rate of the first dilution gas set in the dilution gas supply device 600 may be used as the second flow rate.

After operation S330 is performed, the control device 500 may calculate a first volume percentage of the combustible process gas based on the first flow rate and the second flow rate (S340).

The first volume percentage may be calculated by dividing the flow rate of the combustible process gas by the sum of the flow rate of the first dilution gas and the flow rate of the mixed gas and multiplying the obtained value by 100.

After operation S340 is performed, the control device 500 may determine the supply flow rate of the second dilution gas based on the first volume percentage and the lower explosion limit (S350).

Specifically, when the first volume percentage is greater than the lower explosion limit of the mixed gas, it may be stated that the explosion risk of the mixed gas is high. Accordingly, the control device 500 may control the operation of the dilution gas supply device 600 to supply the second dilution gas to the second discharge line EL2 through the third dilution gas supply line DL3. The second dilution gas may be mixed with the mixed gas and the first dilution gas to become exhaust gas, and may be discharged from the substrate processing apparatus 10. On the other hand, when the first volume percentage is less than the lower explosion limit, it may be stated that the explosion risk of the mixed gas is low. Accordingly, the mixed gas may be discharged from the substrate processing apparatus 10 without separately supplying the second dilution gas.

While example embodiments have been particularly shown and described above, it will be apparent to those skilled in the art that various changes in form and details may be made therein without departing from the spirit and scope of the following claims.

What is claimed is:

1. An exhaust method of a substrate processing apparatus, the method comprising:
measuring a first flow rate for each of process gases included in a mixed gas supplied to a process chamber;
determining, based on the first flow rate, a lower explosion limit of the mixed gas and a first volume percentage of a combustible process gas among the process gases;
determining a supply flow rate of a first dilution gas based on the first volume percentage and the lower explosion limit; and
supplying, at the determined supply flow rate of the first dilution gas, the first dilution gas to the mixed gas in the process chamber.

2. The exhaust method of claim 1, wherein the supplying the first dilution gas comprises:
based on the first volume percentage being greater than the lower explosion limit, supplying the first dilution gas to the mixed gas; and
based on the first volume percentage being less than the lower explosion limit, preventing supply of the first dilution gas to the mixed gas.

3. The exhaust method of claim 1, wherein the first dilution gas comprises nitrogen.

4. The exhaust method of claim 1, further comprising determining an upper explosion limit of the mixed gas using the first flow rate,
wherein the determining the supply flow rate of the first dilution gas comprises determining the supply flow rate of the first dilution gas based on the lower explosion limit, the upper explosion limit, and the first volume percentage.

5. The exhaust method of claim 4, further comprising, based on the first volume percentage being greater than the lower explosion limit and the first volume percentage is less than the upper explosion limit, supplying the first dilution gas to the mixed gas.

6. The exhaust method of claim 1, further comprising:
measuring a second flow rate of the first dilution gas supplied to the process chamber;
determining a second volume percentage of the combustible process gas among the process gases based on the first flow rate and the second flow rate;
determining a supply flow rate of a second dilution gas based on the second volume percentage and the lower explosion limit; and
supplying, at the determined supply rate of the second dilution gas, the second dilution gas to a first exhaust gas in which the first dilution gas and the mixed gas are mixed.

7. The exhaust method of claim 6, wherein the supplying the second dilution gas comprises:
based on the second volume percentage being greater than the lower explosion limit, supplying the second dilution gas to the first exhaust gas; and
based on the second volume percentage being less than the lower explosion limit, preventing supply of the second dilution gas to the first exhaust gas.

8. The exhaust method of claim 6, further comprising determining an upper explosion limit of the mixed gas using the first flow rate,
wherein the determining the supply flow rate of the second dilution gas comprises determining the supply flow rate of the second dilution gas based on the upper explosion limit, the lower explosion limit, and the second volume percentage.

9. The exhaust method of claim 6, further comprising:
measuring a third flow rate for the second dilution gas supplied to the first exhaust gas;
determining a third volume percentage of the combustible process gas among the process gases based on the first flow rate, the second flow rate, and the third flow rate;
determining a supply flow rate of a third dilution gas based on the third volume percentage and the lower explosion limit; and
supplying, at the determined supply flow rate of the third dilution gas, the third dilution gas to a second exhaust gas in which the first exhaust gas and the second dilution gas are mixed.

10. The exhaust method of claim 9, wherein the supplying the third dilution gas comprises:
based on the third volume percentage being greater than the lower explosion limit, supplying the third dilution gas to the second exhaust gas; and
based on the third volume percentage being less than the lower explosion limit, preventing supply of the third dilution gas to the second exhaust gas.

11. The exhaust method of claim 9, further comprising determining an upper explosion limit of the mixed gas using the first flow rate,
wherein the determining the supply flow rate of the third dilution gas comprises determining the supply flow rate of the third dilution gas based on the lower explosion limit, the upper explosion limit, and the third volume percentage.

12. A substrate processing apparatus comprising:
a mixed gas supply device configured to supply a mixed gas in which process gases are mixed;
a process chamber located downstream from the mixed gas supply device and configured to perform substrate processing using the mixed gas;
a pump located downstream from the process chamber;
a scrubber located downstream from the pump and configured to scrub the mixed gas discharged from the process chamber;
a dilution gas supply device configured to supply dilution gas to the mixed gas; and
a control device configured to control the dilution gas supply device,
wherein the control device is configured to:
determine, based on a first flow rate for each of the process gases, a lower explosion limit of the mixed gas and a first volume percentage of a combustible process gas among the process gases, and
control the dilution gas supply device to determine a supply flow rate of a first dilution gas based on the lower explosion limit and the first volume percentage.

13. The substrate processing apparatus of claim 12, wherein the control device is further configured to control the dilution gas supply device to supply, at the determined supply flow rate of the first dilution gas, the first dilution gas to the process chamber.

14. The substrate processing apparatus of claim 12, wherein the control device is further configured to:
determine a second volume percentage of the combustible process gas based on the first flow rate and a second flow rate of the first dilution gas, and
control the dilution gas supply device to determine a supply flow rate of a second dilution gas based on the lower explosion limit and the second volume percentage.

15. The substrate processing apparatus of claim 14, wherein the dilution gas supply device is further configured to supply the second dilution gas to the pump.

16. The substrate processing apparatus of claim 14, wherein the control device is further configured to:
determine a third volume percentage of the combustible process gas using the first flow rate, the second flow rate, and a third flow rate of the second dilution gas, and
control the dilution gas supply device to determine a supply flow rate of a third dilution gas based on the lower explosion limit and the third volume percentage.

17. The substrate processing apparatus of claim 16, further comprising a discharge line connecting the pump to the scrubber,
wherein the dilution gas supply device is further configured to supply the third dilution gas to the discharge line.

18. An exhaust method of substrate processing apparatus, the method comprising:
measuring a first flow rate for each of process gases included in a mixed gas supplied to a process chamber;
determining a lower explosion limit of the mixed gas based on the first flow rate;
measuring a second flow rate of a first dilution gas supplied to a pump located downstream from the process chamber;
determining a first volume percentage of a combustible process gas among the process gases based on the first flow rate and the second flow rate;
determining a supply flow rate of a second dilution gas based on the first volume percentage and the lower explosion limit;
supplying, at the determined supply rate of the second dilution gas, the second dilution gas to a discharge line connected to the pump; and
discharging an exhaust gas in which the mixed gas, the first dilution gas, and the second dilution gas are mixed.

19. The exhaust method of claim 18, wherein the supplying the second dilution gas comprises, based on the first volume percentage being greater than the lower explosion limit, supplying the second dilution gas to the discharge line.

20. The exhaust method of claim 18, wherein the first dilution gas and the second dilution gas comprise a same material.
